(19) United States
(12) Patent Application Publication
(10) Pub. No.: US 2019/0067567 A1
(43) Pub. Date: Feb. 28, 2019

(54) RESISTIVE RANDOM ACCESS MEMORY

(71) Applicant: UNITED MICROELECTRONICS CORP., Hsin-Chu City (TW)

(72) Inventor: Yuan-Heng Tseng, Pingtung County (TW)

(21) Appl. No.: 15/717,958

(22) Filed: Sep. 28, 2017

(30) Foreign Application Priority Data
Aug. 29, 2017 (CN) 201710755238.9

(51) Int. Cl. H01L 45/00; H01L 27/24

(52) U.S. Cl. CPC H01L 45/122; G11C 13/0069; H01L 27/2436; H01L 27/2463

(57) ABSTRACT

A resistive random access memory (RRAM) includes: a substrate having a first cell region and a second cell region; a fin-shaped structure extending along a first direction on the substrate across the first cell region and the second cell region; a first word line extending along a second direction on the first cell region; a source line extending along the second direction between the first cell region and the second cell region; and a single diffusion break (SDB) structure extending along the second direction directly under the source line.

### BACKGROUND OF THE INVENTION

### 1. Field of the Invention

The invention relates to a resistive random access memory (RRAM), and more particularly to a RRAM having a single diffusion break (SDB) structure disposed directly under source line.

### 2. Description of the Prior Art

Resistive elements can be used as semiconductor switches or memory elements (e.g., memory cells of a memory device), among other applications. Memory devices are typically provided as internal, semiconductor, integrated circuits in computers or other electronic devices. There are many different types of memory, including random-access memory (RAM), read only memory (ROM), dynamic random access memory (DRAM), synchronous dynamic random access memory (SDRAM), flash memory, resistance variable memory such as phase change random access memory (PCRAM), and resistive random access memory (RRAM), among others.

Non-volatile resistive memory such as RRAM devices store data by varying the resistance of a resistance element. RRAM devices can have certain beneficial characteristics over other types of memory devices, such as low power consumption, high speed, and excellent bit resolution due to separation and a relatively large resistance ratio between a high resistance state (FIRS) and a low resistance state (LRS), without the read/write cycle endurance limitations of charge-storage type memory.

Data may be written to a selected RRAM device by applying a predetermined voltage, at a predetermined polarity, for a predetermined duration. RRAM devices can be operated using two types switching: unipolar or bipolar. Unipolar switching involves programming and erasing using long and short pulses having the same voltage polarity. In contrast, bipolar switching uses short pulses, but programming and erasing pulses are of opposite polarity. Nevertheless, as current RRAM devices still reside numerous shortcomings, novel RRAM devices having improved performance continue to be sought.

### SUMMARY OF THE INVENTION

According to an embodiment of the present invention, a resistive random access memory (RRAM) includes: a substrate having a first cell region and a second cell region; a fin-shaped structure extending along a first direction on the substrate across the first cell region and the second cell region; a first word line extending along a second direction on the first cell region; a source line extending along the second direction between the first cell region and the second cell region; and a single diffusion break (SDB) structure extending along the second direction directly under the source line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a top view of a RRAM according to an embodiment of the present invention.

FIG. 2 illustrates a cross-section view of FIG. 1 along the sectional line AA′.

FIG. 3 is a perspective diagram illustrating a means of programming a RRAM device according to an embodiment of the present invention.

FIG. 4 is a perspective diagram illustrating a means of programming a RRAM device according to an embodiment of the present invention.

### DETAILED DESCRIPTION

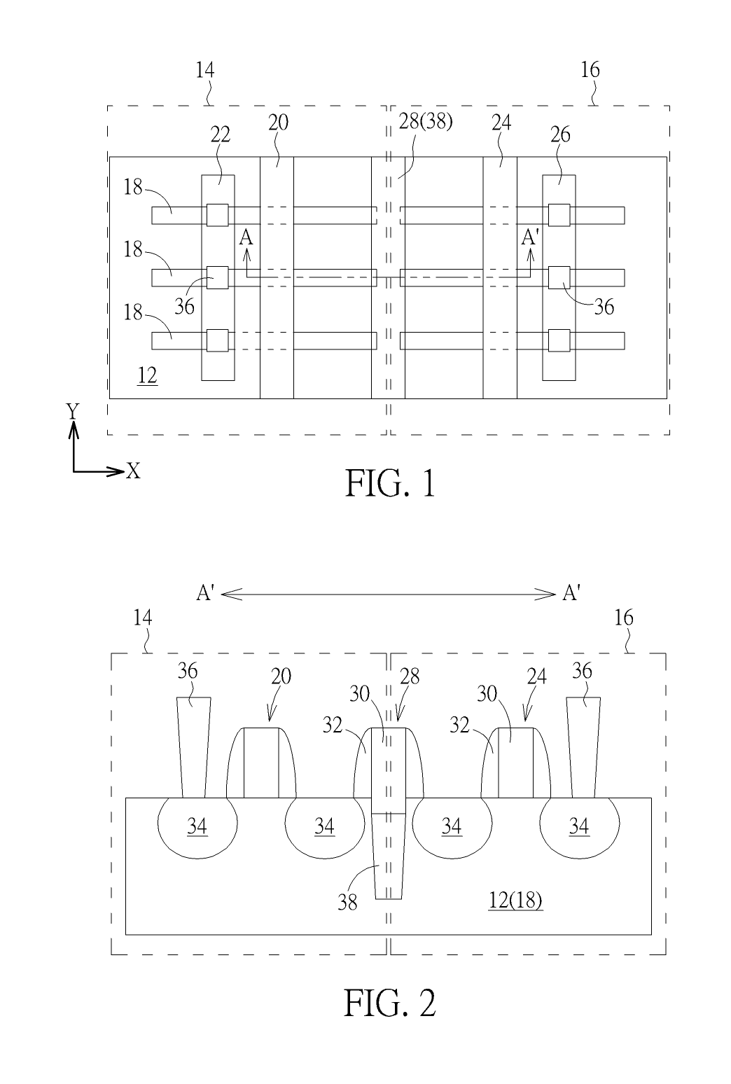

Referring to FIGS. 1-2, FIG. 1 illustrates a top view of a RRAM according to an embodiment of the present invention and FIG. 2 illustrates a cross-section view of FIG. 1 along the sectional line AA′. As shown in FIGS. 1-2, the RRAM preferably includes a substrate 12 such as a silicon substrate or silicon-on-insulator (SOI) substrate and a first cell region 14 and a second cell region 16 defined on the substrate 12.

A plurality of fin-shaped structures 18 are disposed extending along a first direction (such as x-direction) on the substrate 12 from the first cell region 14 to the second cell region 16, a first word line 20 is disposed extending along a second direction (such as y-direction) on the first cell region 14, a first bit line 22 is disposed extending along the second direction on the left side of the first word line 20, a second word line 24 is disposed extending along the second direction on the second cell region 16, a second bit line 26 is disposed extending along the second direction on the right side of the second word line 24, and a source line 28 is disposed extending along the second direction between the first cell region 14 and the second cell region 16. Preferably, the source line 28 is disposed to cover part of the first cell region 14 and part of the second cell region 16 at the same time.

According to an embodiment of the present invention, the fin-shaped structure 18 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 18 could also be obtained by first forming a patterned mask (not shown) on the substrate, 12, and through an etching process, the pattern of the patterned mask is transferred to the substrate 12 to form the fin-shaped structure. Moreover, the formation of the fin-shaped structure could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure. These approaches for forming fin-shaped structure are all within the scope of the present invention.

As shown in FIG. 2, each of the word lines 20, 24 and the source line 28 preferably includes a gate structure 30 and a spacer 32 disposed around the gate structure 30, source/drain regions 34 are disposed in the fin-shaped structures 18 adjacent to two sides of the word lines 20, 24 and the source line 28, a dielectric layer (not shown) such as an interlayer dielectric (ILD) layer is disposed to cover the word lines 20, 24, the source line 28, and the source/drain region 34, and bit line contacts 36 are disposed penetrating the dielectric layer to electrically connect the source/drain regions 34 on one side of the word line 20 and on another side of the word line 24 to the bit lines 22, 26. Preferably, the source/drain regions 34 adjacent to two sides of the source line 28 are floating regions. In other words, no contact plugs are formed on the source/drain regions 34 adjacent to two sides of the source line 28 and the dielectric layer or ILD layer is directly contacting and covering the source/drain regions 34 so that the source/drain regions 34 adjacent to two sides of the source line 28 could not electrically connect to other devices through contact plugs.

In this embodiment, each of the gate structures 30 includes a metal gate and the fabrication of the gate structures 30 could be accomplished by a gate first process, a high-k first process from a gate last process, or a high-k last process from the gate last process. In this embodiment, each of the gate structures 30 or metal gates could include elements such as but not limited to for example interfacial layer, high-k dielectric layer, work function metal layer, and low-resistance metal layer.

In this embodiment, the high-k dielectric layer is preferably selected from dielectric materials having dielectric constant (k value) larger than 4. For instance, the high-k dielectric layer 54 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer is formed for tuning the work function of the metal gate in accordance with the conductivity of the device. For an NMOS transistor, the work function metal layer having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer and the low resistance metal layer, in which the material of the barrier layer may include titanium (Ti), titanium nitride (TiN), tantalum (Ta) or tantalum nitride (TaN). Furthermore, the material of the low-resistance metal layer may include copper (Cu), aluminum (Al), titanium aluminum (TiAl), cobalt tungsten phosphide (CoWP) or any combination thereof.

In this embodiment, each of the spacers 32 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The source/drain regions 34 could include dopants and epitaxial material of different conductive type depending on the type of device being fabricated. For example, the source/drain regions 34 on an NMOS region could include SiC or SiP while the source/drain regions 34 on an PMOS region could include SiGe, but not limited thereto.

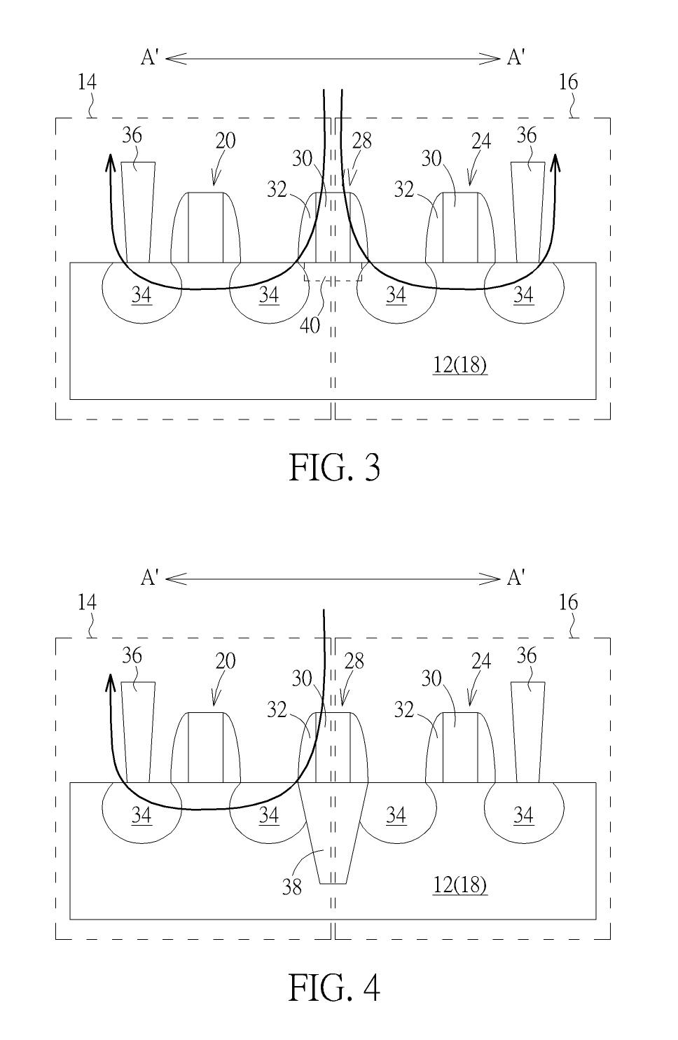

It should be noted that the RRAM of this embodiment preferably includes a single diffusion break (SDB) structure 38 extending along the second direction directly under the source line 28, in which the SDB structure 38 overlaps the source line 28 if viewed from the top view diagram as shown in FIG. 1. As shown in FIG. 2, the SDB structure 38 is disposed directly under the source line 28, in which the SDB structure 38 could be made of dielectric material including but not limited to for example silicon oxide or silicon nitride. It should be noted that even though the top surface of the SDB structure 38 is slightly lower than the top surface of the adjacent fin-shaped structures 18 and two sidewalls of the SDB structure 38 are aligned with the two sidewalls of the gate structure 30, according to an embodiment of the present invention, the top surface of the SDB structure 38 could also be even with the top surface of the fin-shaped structures 18 and the two sidewalls of the SDB structure 38 could be extended outward to be aligned with the sidewalls of the spacer 32 as shown in FIG. 4, which are all within the scope of the present invention.

Referring to FIGS. 3-4, FIGS. 3-4 are perspective diagrams illustrating a comparison between programming different RRAM devices according to an embodiment of the present invention. Preferably, no SDB structure is disposed directly under the source line 28 in the RRAM shown in FIG. 3 while a SDB structure 38 similar to the one disclosed in FIG. 2 is disposed directly under the source line 28 in the RRAM shown in FIG. 4.

As shown in FIG. 3, when no SDB structure is disposed directly under the source line 28, the transistor of the source line 28 would be turned on after applying a high voltage to the source line 28 and a channel region 40 would be formed directly under the source line 28 transistor. If the first cell region 14 is programmed at this moment such as by applying 0 volts to the first bit line 22, the first word line 20 would be turned on and 0 volts would be passed to the floating source/drain region 34 and a breakdown would result by the voltage difference between 0 volts and 1 volt. This however induces the second cell region 16 to breakdown at the same due to the existence of the channel region 40 directly under the source line 28 transistor thereby causing disturbance to the first cell region 14. As a result it would have been impossible for the RRAM device to generate 2 bits in an operation.

In contrast to the operating mechanism shown in FIG. 3, the structure shown in FIG. 4 operates a scheme by disposing a SDB structure 38 directly under the gate structure 30 of the source line 28 and the presence of the SDB structure 38 guarantees that no channel inversion would take place in at least one of the first cell region 14 or the second cell region 16. In other words, as no channel region is present directly under the source line, the structure is able to guarantee that no disturbance would result when the two cell regions are operated under programming mode.

Those skilled in the art will readily observe that numerous modifications and alterations of the device and method may be made while retaining the teachings of the invention. Accordingly, the above disclosure should be construed as limited only by the metes and bounds of the appended claims.

1. A memory device, comprising:
a substrate having a first cell region and a second cell region;
a fin-shaped structure extending along a first direction on the substrate across the first cell region and the second cell region;
a first word line extending along a second direction on the first cell region;
a source line extending along the second direction between the first cell region and the second cell region, wherein the source line comprises a gate structure and a spacer around the gate structure;
a single diffusion break (SDB) structure extending along the second direction directly under the source line, wherein two sidewalls of the SDB structure are aligned with two sidewalls of the gate structure;
a first source/drain region adjacent to one side of the first word line;
a contact plug connecting the first source/drain region directly; and
a second source/drain region immediately adjacent to another side of the first word line and immediately adjacent to the source line, such that the second source/drain region is between the first word line and the source line, wherein the second source/drain region is floating.

2. The memory device of claim 1, further comprising a second word line extending along the second direction on the second cell region.

3. The memory device of claim 1, wherein the source line is disposed on part of the first cell region.

4. The memory device of claim 1, wherein the source line is disposed on part of the second cell region.

5-7. (canceled)

8. The memory device of claim 1, wherein a top surface of the SDB structure is lower than a top surface of the fin-shaped structure.

9. The memory device of claim 1, wherein the SDB structure comprises silicon oxide or silicon nitride.

10. The memory device of claim 1, wherein the first direction is orthogonal to the second direction.

11. A memory device, comprising:
a substrate having a first cell region and a second cell region;
a fin-shaped structure extending along a first direction on the substrate across the first cell region and the second cell region;
a first word line extending along a second direction on the first cell region;
a source line extending along the second direction between the first cell region and the second cell region, wherein the source line comprises a gate structure and a spacer around the gate structure;
a single diffusion break (SDB) structure extending along the second direction directly under the source line, wherein two sidewalls of the SDB structure are aligned with two sidewalls of the spacer;
a first source/drain region adjacent to one side of the first word line;
a contact plug connecting the first source/drain region directly; and
a second source/drain region immediately adjacent to another side of the first word line and immediately adjacent to the source line, such that the second source/drain region is between the first word line and the source line, wherein the second source/drain region is floating.

12. The memory device of claim 1, wherein the first word line does not overlap either the first source/drain region or the second source/drain region, and the gate structure does not overlap the second source/drain region.
